(19) United States
(12) Patent Application Publication
(10) Pub. No.: US 2008/0211044 A1
(43) Pub. Date: Sep. 4, 2008

(54) Micro-electro-mechanical systems device

(75) Inventors: Tamotsu Akashi, Kawasaki (JP); Tsuyoshi Yamamoto, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/071,513

(22) Filed: Feb. 21, 2008

(30) Foreign Application Priority Data
Feb. 21, 2007 (JP) 2007-040669

(51) Int. Cl. H01L 29/84

(52) U.S. Cl. 257/415; 257/E29.324

(57) ABSTRACT

According to an aspect of an embodiment, a micro-electro-mechanical systems (MEMS) device comprises a substrate, a MEMS and a movable absorber.

The MEMS has a movable part having a resonance frequency on the substrate. The movable absorber absorbs a vibration in accordance with the resonance frequency so as to vibrate itself.

### FIELD OF THE INVENTION

This art relates to devices using micro-electro-mechanical systems (MEMS) elements. More specifically, a MEMS device accommodates MEMS element(s), which has a vibration-proof structure.

MEMS devices have movable parts, i.e., mechanical elements fabricated by a semiconductor integrated circuit fabrication technology or the like, that are mechanically driven by using electricity. Optical switches are one example of systems using MEMS devices. Optical switches having a variety of structures have been proposed. Among those devices, an optical switch using a MEMS mirror array, which can provide a compact-sized multi-channel switch, is currently under development for practical application.

However, because MEMS mirrors are movable mechanical structures, they may be moved out of position when they are subject to an externally applied vibration or impact. This disturbs optical paths. Therefore, as disclosed in Japanese Laid-open Patent Publication No. 2006-35375, MEMS mirrors are typically protected from an externally applied vibration or impact using a damper made of vibration-proof rubber. The rubber exchanges a gel being a more flexible material than the rubber.

Examples of known structures of MEMS mirrors for optical switches include a structure in which each of the MEMS mirrors pivots about a single axis, which is disclosed in U.S. Pat. No. 6,753,960, and a structure in which each of the MEMS mirrors pivots about two axes, which is disclosed in U.S. Pat. No. 6,591,029. In both structures, the MEMS mirrors are arranged in an array on a semiconductor substrate.

Because MEMS mirrors are movable mechanical structures, they have a resonance frequency (a natural frequency) determined by their shape and material. If the frequency components of an externally applied vibration or impact include the resonance frequency of the MEMS mirrors, the MEMS mirrors resonate. This significantly disturbs optical paths. Accordingly, parameters such as hardness of a vibration-proof damper need to be adjusted to sufficiently attenuate the vibration.

U.S. Pat. No. 6,591,029 discloses that light emitted from an input fiber is reflected at an input MEMS mirror, and then reflected at an output MEMS mirror to an output fiber. That is, in one optical path, light is reflected at two MEMS mirrors having four pivot axes. When the MEMS mirrors having four pivot axes, which are disclosed in U.S. Pat. No. 6,591,029, are subject to an externally applied vibration or impact, they may be moved by an amount four times greater than an amount by which the MEMS mirrors having a single pivot axis, which are disclosed in Japanese Unexamined Patent Application Publication No. 2006-35375 and U.S. Pat. No. 6,753,960, are moved. Accordingly, for example, the structure disclosed in U.S. Pat. No. 6,591,029 requires a vibration absorbing damper for absorbing an externally applied vibration having a vibration attenuation capability four times larger than the vibration attenuation capability of the vibration absorbing dampers required by the structures disclosed in the other patent documents. A MEMS device having MEMS mirrors, each having four pivot axes, requires a vibration transmissibility of about −80 dB if the resonance frequency of the MEMS mirrors is in the range of about 1 kHz to 2 kHz.

FIG. 1 shows a measurement example of the vibration transmissibility of a simple damper made of vibration-proof rubber, which is a known vibration-proof structure. The known damper made of vibration-proof rubber provides a vibration attenuation of about −40 dB to −50 dB. When the frequency component of an externally applied vibration or impact includes the resonance frequency of the MEMS mirrors, as described above, the vibration attenuation capability is insufficient.

Therefore, there is a problem in that the vibration attenuation capability becomes insufficient when the MEMS mirrors are subject to an externally applied vibration having the resonance frequency of the MEMS mirrors, whereby the MEMS mirrors undergo resonant vibration. In addition, the resonant vibration of the MEMS mirrors degrades the optical properties of the optical switch.

In a device such as an optical switch, a plurality of MEMS mirrors are arranged along an optical path. Therefore, light propagating in the optical switch tends to be influenced by the resonance of the MEMS mirrors.

### SUMMARY

According to an aspect of an embodiment, a micro-electro-mechanical systems (MEMS) device comprises a substrate, a MEMS and a movable absorber.

The MEMS has a movable part having a resonance frequency on the substrate. The movable absorber absorbs a vibration in accordance with the resonance frequency so as to vibrate itself.

### BRIEF DESCRIPTION OF THE DRAWINGS

FIG. 1 is a graph showing the vibration transmissibility of a known vibration-proof structure;

FIG. 2 shows a structure of a MEMS device of the embodiment;

FIG. 3 shows a structure of an optical switch;

FIGS. 4A and 4B show a structure of a movable part in a MEMS mirror array;

FIG. 5 shows a first exemplary structure of a vibration absorber;

FIG. 6 shows a second exemplary structure of the vibration absorber;

FIG. 7 shows a third exemplary structure of the vibration absorber;

FIG. 8 shows a fourth exemplary structure of the vibration absorber;

FIG. 9 is a graph showing the vibration transmissibility of the vibration absorber shown in FIG. 5;

FIG. 10 shows a structure of a vibration absorber for a casing; and

FIGS. 11A to 11C show a structure of a second MEMS device including a MEMS element having a single axis structure.

### DESCRIPTION OF THE PREFERRED EMBODIMENTS

These embodiments provide a MEMS device capable of sufficiently attenuating mechanical resonance, even when the MEMS device includes a plurality of MEMS elements having the same resonance frequency, and even when the MEMS device is subject to an externally applied vibration having a frequency the same as the resonance frequency of movable parts of the MEMS elements.

Embodiments will now be described with reference to the drawings. It is to be noted that configurations of the following embodiments are exemplary, and these embodiments are not limited thereto.

### Structure of MEMS Device

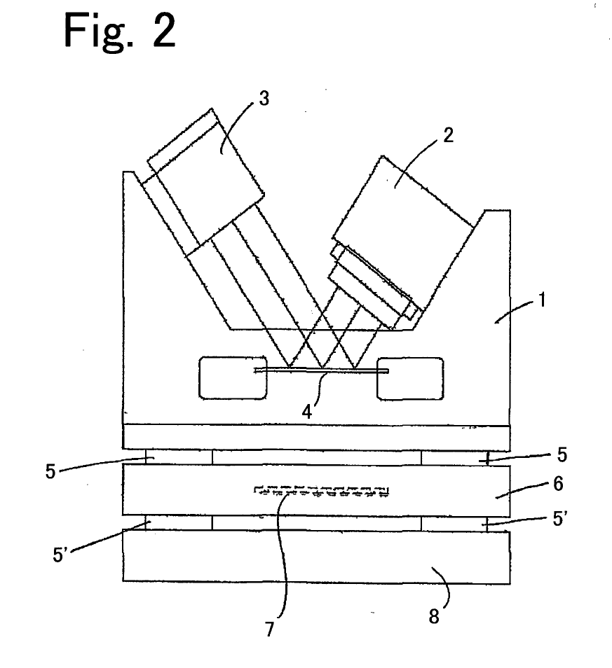

FIG. 2 shows a structure of a MEMS device of the embodiment. The MEMS device includes a casing 1, an optical input/output portion 2, an optical path bending mirror 3, a MEMS mirror array 4 (MEMS elements), vibration-proof rubber members 5 and 5′, a vibration absorber 6, a movable absorbing portion 7, and a base 8.

The casing 1 has two slant surfaces arranged to form a substantially V-shaped structure with a horizontal bottom portion. The optical input/output portion 2 is arranged on one of the slant surfaces of the casing 1. The optical path bending mirror 3 is arranged on the other one of the slant surfaces of the casing 1. The MEMS mirror array 4 is arranged on the horizontal portion at the bottom of the V-shaped structure of the casing 1. The vibration absorber 6 and the vibration-proof rubber members 5 and 5′ are arranged between the casing 1 and the base 8. The base 8 serves as a foundation for fixing the MEMS device to an external member. The vibration-proof rubber members 5 and 5′ may be made of a gel. The vibration-proof rubber members 5 and 5′ are elastic members for absorbing externally applied vibration by being elastically deformed. The movable absorbing portion 7 is arranged within the vibration absorber 6.

An externally applied vibration or impact (propagated from the base 8) is partially absorbed by the vibration-proof rubber members 5′, similarly to the known structure, and then the remaining portion of the vibration having a frequency component the same as that of the MEMS mirrors is absorbed at the vibration absorber 6. The vibration-proof rubber members 5 further attenuate the vibration. The vibration-proof rubber members 5 prevent both MEMS mirrors 4 and movable absorbing portions 7 of the vibration absorber 6 from vibrating.

### Structure of Optical Switch

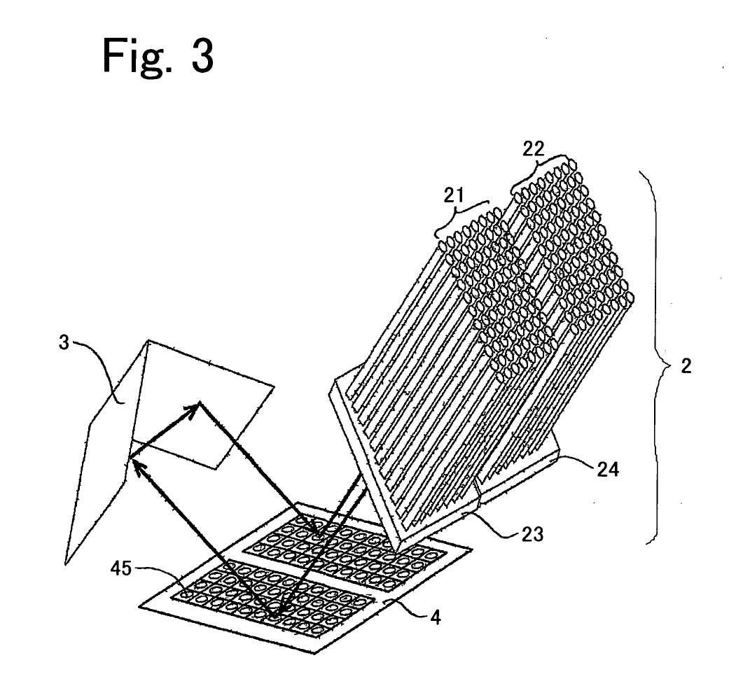

FIG. 3 shows an optical structure of the MEMS device shown in FIG. 2. In FIG. 3, components the same as those shown in FIG. 2 are denoted by the same reference numerals. First, structures of respective portions will be described.

The optical input/output portion 2 includes an input optical fiber array 21, an output optical fiber array 22, an input lens array 23, and an output lens array 24. In the optical input/output portion 2, each of the fibers of the input optical fiber array 21 corresponds to one of the lenses in the input lens array 23. Similarly, each of the fibers of the output optical fiber array 22 corresponds to one of the lenses in the output lens array 24.

The MEMS mirror array 4 includes the MEMS mirrors 45. The number of the MEMS mirrors 45 of the MEMS mirror array 4 equals the number of the fibers of the input fiber array 21 and the output fiber array 22 of the optical input/output portion 2. Some of the MEMS mirrors 45 correspond to the input lens array 23, and the others correspond to the output lens array 24.

The optical path bending mirror 3 includes a first mirror and a second mirror. The first mirror reflects light beams from the MEMS mirror array 4 onto the second mirror, where the light beams are reflected back in the direction of the MEMS mirror array 4.

Referring to FIG. 3, optical paths in the optical switch will be described. The input lens array 23 converts light propagated in the input optical fiber array 21 into light beams, which are suitable for propagation through space. The input lens array 23 emits the converted light beams onto the MEMS mirrors 45 of the MEMS mirror array 4 corresponding to the input fiber array 21. The MEMS mirror 45 reflects the light beams emitted from the input optical lens array 23 onto the optical path bending mirror 3, where the light beams are reflected back onto the MEMS mirrors 45 of the MEMS mirror array 4 corresponding to the output fiber array 22. The MEMS mirrors 45 reflect the light beams from the optical path bending mirror 3 onto the output lens array 24 corresponding to the MEMS mirrors 45. The output lens array 24 converges the light beams from the MEMS mirrors 45 so that the light can propagate through the output optical fiber array 22. The output optical fiber array 22 allows the light to propagate to the outside of the optical switch. By controlling the angles of the MEMS mirrors 45, the optical switch can change optical paths. Thus, the optical switch can output light to a desired output optical fiber.

In the structure in which the MEMS mirrors bend the optical path several times, as described above, the MEMS mirrors, each having a plurality of pivot axes, are arranged in an array. This produces mechanical vibrations in the same direction, having the same resonance frequency.

### Structure of Movable Part of MEMS Mirror Array

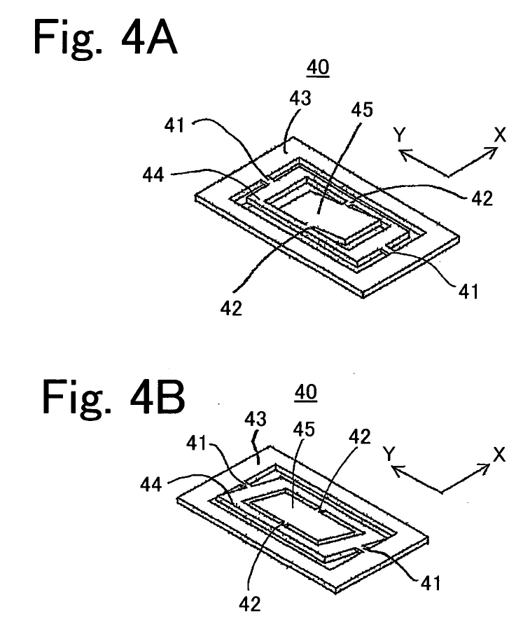

FIGS. 4A and 4B show a structure of a movable part 40 of the MEMS mirror array 4. The movable part 40 includes a pair of Y-axis rotational hinges 41, a pair of X-axis rotational hinges 42, a first frame 43, a second frame 44, and the MEMS mirror 45. The first frame 43 supports the second frame 44 with the pair of Y-axis rotational hinges 41. The second frame 44 supports the MEMS mirror 45 with the pair of X-axis rotational hinges 42. The MEMS mirror 45 is capable of rotation (movement) about the X-axis rotational hinges 42. An actuator rotates the MEMS mirror 45. The second frame 44 is capable of rotation (movement) about the Y-axis rotational hinges 41. The actuator rotates the second frame 44. The X-axis rotational hinges 42 and the Y-axis rotational hinges 41 are provided perpendicular to each other.

FIG. 4A shows the MEMS mirror 45 rotated about the X-axis. FIG. 4B shows the second frame 44 rotated about the Y-axis. The movable part 40 of the MEMS mirror 45 can be rotated about the X-axis and the Y-axis in combination, if necessary.

### Structures of Vibration Absorber

### 1. First Exemplary Structure of Vibration Absorber:

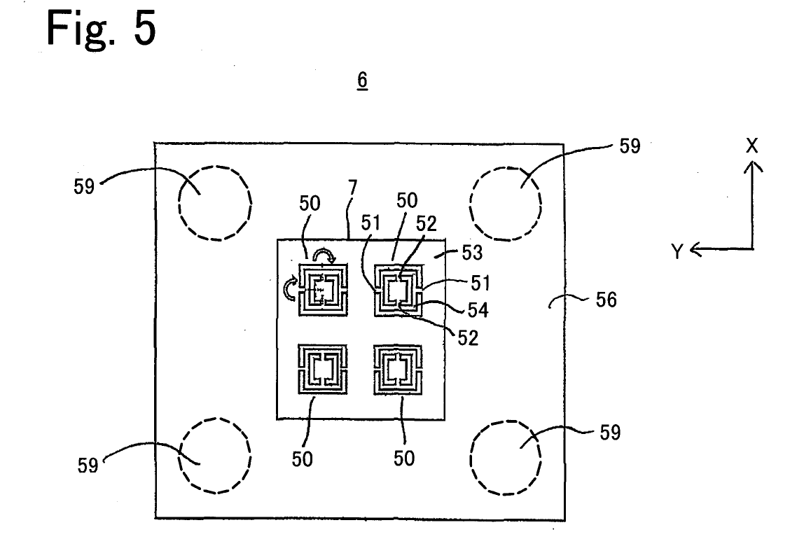

FIG. 5 shows a first exemplary structure of the vibration absorber 6 shown in FIG. 2. The vibration absorber 6 includes the movable-absorbing-portion array 7 and a housing 56. The movable-absorbing-portion array 7 includes movable absorbing portions 50. FIG. 5 shows four movable absorbing portions 50. The housing 56 has vibration-proof-rubber-members attaching portions 59 to which the vibration-proof rubber members 5 and 5′ will be attached. The vibration-proof-rubber-members attaching portions 59 are provided on both the top and bottom surfaces of the housing 56. The vibration absorber 6 is arranged parallel to the MEMS mirror array 4, as shown in FIG. 2, whereby the movable absorbing portions 50 of the vibration absorber 6 are arranged substantially parallel to the movable parts 40 of the MEMS mirror array 4.

The movable absorbing portions 50 are pseudo-MEMS elements, i.e., the movable absorbing portions 50 have the same oscillation characteristics as the MEMS mirrors 45. Therefore, the movable absorbing portions 50 have the same resonance frequency and similar pivot axes as the MEMS mirrors 45. That is, each of the movable absorbing portions 50 has a pair of Y-axis rotational hinges 51, a pair of X-axis rotational hinges 52, a first frame 53, a second frame 54, and an oscillating body 55. The first frame 53 supports the second frame 54 with the pair of Y-axis rotational hinges 52. The second frame 54 supports the oscillating body 55 with the pair of X-axis rotational hinges 52. The X-axis rotational hinges 52 and the Y-axis rotational hinges 51 are provided perpendicular to each other.

The oscillating body 55 is capable of movement about the X-axis rotational hinges 52. A vibration propagated from the base 8 oscillates the oscillating body 55 about the X-axis rotational hinges 52. This oscillation has the same resonance frequency as the MEMS mirror 45. Accordingly, vibration energy propagated from the base 8 can be reduced by oscillating the oscillating body 55.

The second frame 54 is capable of movement about the Y-axis rotational hinges 51. A vibration propagated from the base 8 oscillates the second frame 54 about the Y-axis rotational hinges 51, along with the oscillating body 55. This oscillation has the same resonance frequency as the MEMS mirror 45. Accordingly, vibration energy propagated from the base 8 can be reduced by oscillating the oscillating body 55 through the second frame.

The vibration absorption capability of the vibration absorber 6 depends on the number of the movable absorbing portions 50. Thus, the number of the movable absorbing portions 50 should be determined according to the vibration transmissibility required by the system.

Because the movable absorbing portions 50 and the movable parts 40 have the same resonance frequency, their shapes are geometrically similar. In other words, the structures of the movable absorbing portions 50 and the movable parts 40 are the same. Further, the MEMS mirror array itself may serve as the vibration absorber 6. When the MEMS mirror array serves as the vibration absorber 6, the actuator is not necessary.

### 2. Second Exemplary Structure of Vibration Absorber:

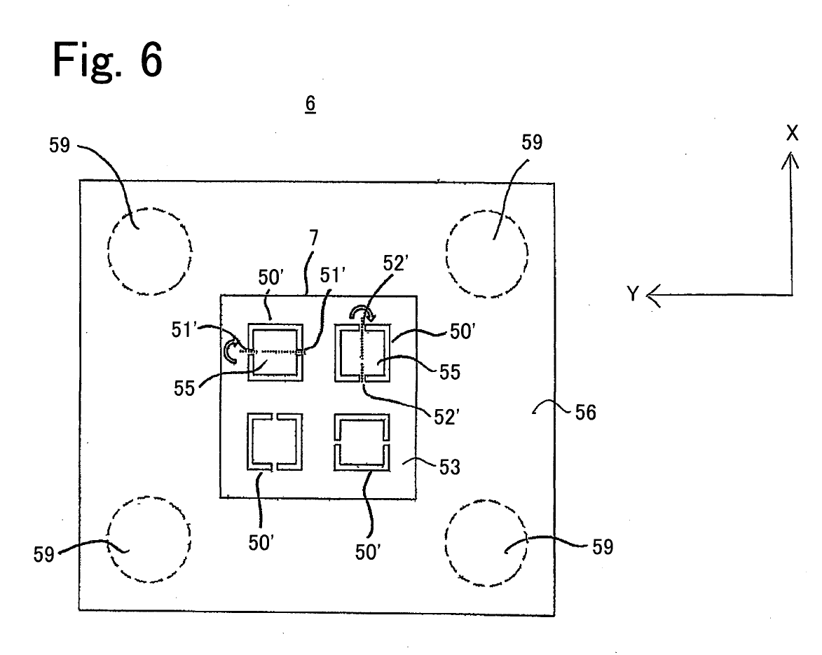

FIG. 6 shows a second exemplary structure of the vibration absorber 6 shown in FIG. 2. If the movable parts 40 have a multi-axis structure having a plurality of moving directions (the X-axis and Y-axis directions) as shown in FIG. 4A and FIG. 4B, the movable absorbing portions 50 of the vibration absorber 6 may be structured to have a plurality of vibration absorbing structures corresponding to the moving directions of the movable parts 40. A structure as shown in FIG. 6 simplifies the process of manufacturing the axes of the movable absorbing portions 50 of the vibration absorber 6.

In FIG. 6, components the same as those shown in FIG. 5 are denoted by the same reference numerals so as to make explanation thereof unnecessary. In FIG. 6, the movable-absorbing-portion array 7 includes two types of movable absorbing portions 50′: one supporting the oscillating body 55 on the first frame 53 with Y-axis rotational hinges 51′; and the other supporting the oscillating body 55 on the first frame 53 with X-axis rotational hinges 52′. Where the resonance frequency=f0, the structure of a single-axis, simple rotational hinge as shown in FIG. 6 can be expressed by the following Expression 1.

$$[ Expression 1 ]$$

$$f 0 = \frac{h}{Lc} \sqrt{\frac{3 BbG}{ρ WLcL}} \qquad ( 1 )$$

h: thickness of mirror and hinge; W: width of mirror; Lc: length of mirror; Lt: length of hinge; b: width of hinge; G: modulus of rigidity; B: constant determined by thickness and width of hinge; and ρ: density

The vibration absorption capability of the vibration absorber 6 depends on the number of the movable absorbing portions 50. Thus, the number of the movable absorbing portions 50 should be determined according to the vibration transmissibility required by the system.

### 3. Third Exemplary Structure of Vibration Absorber:

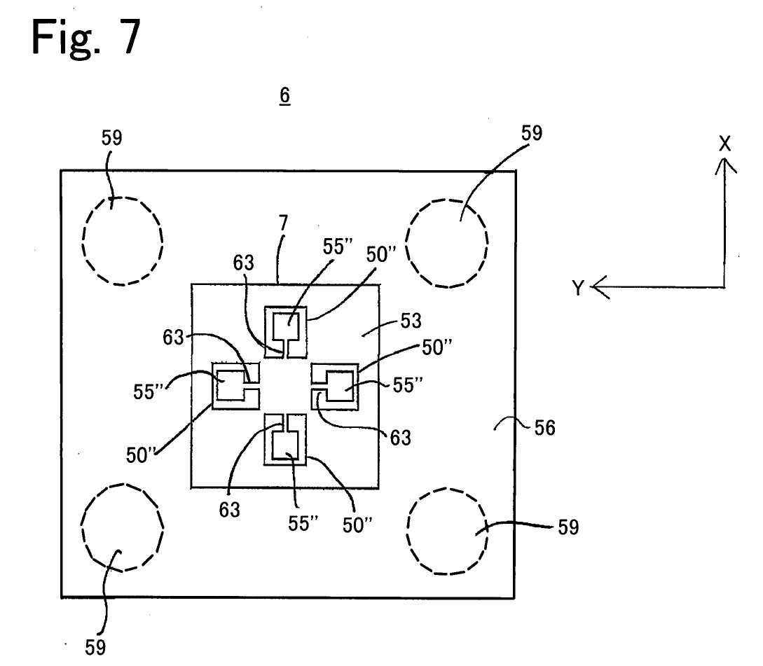

FIG. 7 shows a third exemplary structure of the vibration absorber 6 shown in FIG. 2. In FIG. 7, components the same as those shown in FIG. 5 are denoted by the same reference numerals so as to make explanation thereof unnecessary. Each of movable absorbing portions 50″ in the movable-absorbing-portion array 7 has a hinge 63. The hinge 63 extends from the first frame 53 and supports an oscillating body 55″. In FIG. 7, the oscillating body 55″ positioned at an end of the hinge 63, as a cantilever structure, may be provided with a weight so that the oscillating body 55″ has the same resonance frequency as the MEMS mirrors 45. The oscillating bodies 55″ are arranged radially from the center of the movable-absorbing-portion array 7 with the hinges 63, so as to correspond to the moving directions of the movable parts 40 of the MEMS mirrors. If the movable parts 40 of the MEMS mirrors have two-axis rotational hinges as shown in FIG. 4, it is more effective that the movable absorbing portions 50 of the vibration absorber 6 have the two-axis rotational hinges as shown in FIGS. 5 and 6. However, the hinge 63 of the cantilever structure as shown in FIG. 7 is easier to manufacture than the two-axis rotational hinges as shown in FIGS. 5 and 6. The oscillating bodies 55″ can oscillate at a frequency the same as the resonance frequency of the MEMS mirrors, even with the cantilever-shaped hinge 63.

The vibration absorption capability of the vibration absorber 6 depends on the number of the movable absorbing portions 50″. Thus, the number of the movable absorbing portions 50″ should be determined according to the vibration transmissibility required by the system.

### 4. Fourth Exemplary Structure of Vibration Absorber:

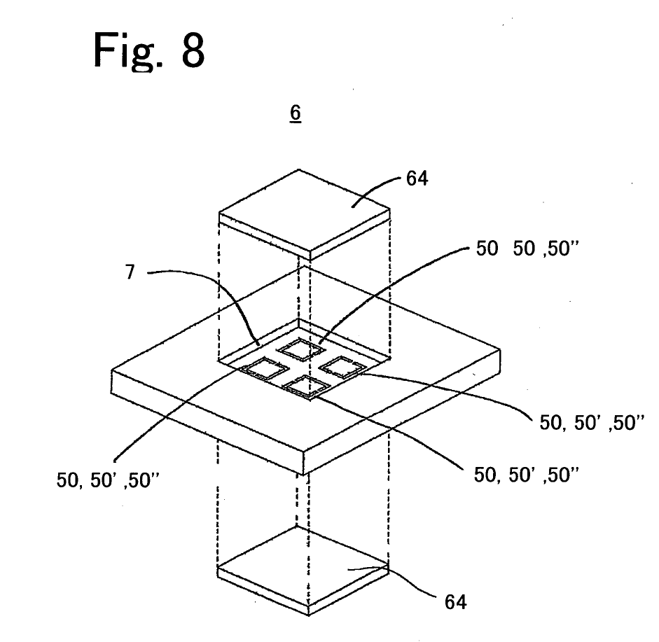

FIG. 8 shows a fourth exemplary structure of the vibration absorber 6 shown in FIG. 2. If the resonance frequency of the movable absorbing portions 50, 50′, and 50″ shown in FIGS. 5, 6, and 7, respectively, and the resonance frequency of the MEMS mirrors 45 are different, the effect of the movable absorbing portions 50, 50′, and 50″ for absorbing vibration is decreased. Accordingly, it is preferable that the half width of the resonance frequency of the movable absorbing portions 50, 50′, and 50″ of the vibration absorber 6 be large. FIG. 8 shows a structure for reducing the Q-value of the resonance of the movable absorbing portions 50, 50′, and 50″ arranged in the vibration absorber 6. More specifically, the movable absorbing portions 50, 50′, and 50″ are provided with attenuators 64 to reduce the Q-value. This increases the range of frequency of the vibration that the movable absorbing portions 50, 50′, and 50″ can absorb. The attenuators 64 may be made of rubber sheets, gel sheets, or the like, and sandwich the movable-absorbing-portion array 7 from above and below. This structure successfully attenuates vibration of the movable absorbing portions 50, 50′, and 50″. If the peak value of the resonance of the movable absorbing portions 50, 50′, and 50″ decreases, the vibration attenuation capability decreases. However, this may be compensated for by increasing the number of the movable absorbing portions 50, 50′, and 50″.

### 5. Exemplary Structure 5 of Vibration Absorber:

Although the resonance frequencies of the movable absorbing portions 50, 50′, and 50″ are determined by Expression 1, there is a certain freedom for modifying Expression 1 to derive the same resonance frequency f0. For example, if the width of mirror is increased to 2W and the width of hinge is increased to 2b, the weights or the moments of inertia of the movable absorbing portions 50, 50′, and 50″ can be changed while maintaining the resonance frequencies of the movable absorbing portions 50, 50′, and 50″. The movable absorbing portions 50, 50′, and 50″ response to an externally imposed impact in various ways according to the magnitudes of their moments of inertia, whereby they become capable of coping with disturbances of any strength and rate. Accordingly, it is preferable that the vibration absorber 6 have a plurality of movable absorbing portions having different moments of inertia.

### Vibration Transmissibility of Vibration Absorber

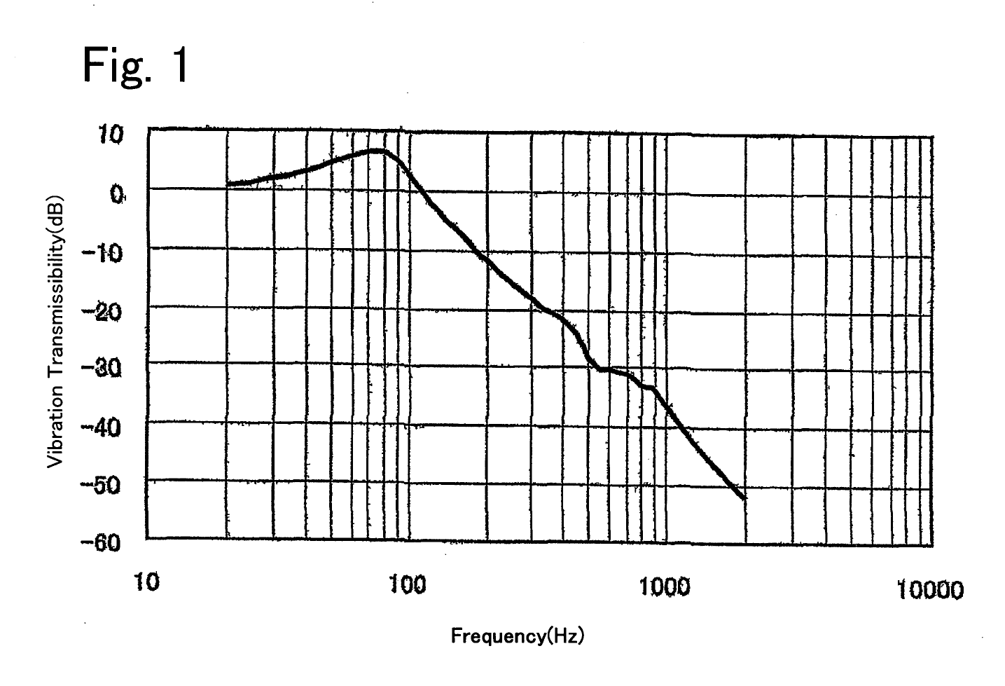

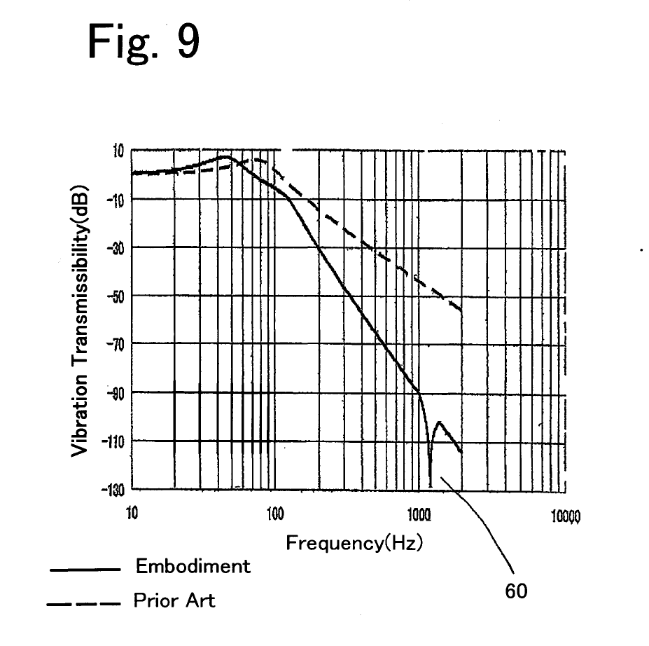

FIG. 9 is a graph showing the vibration transmissibility of the vibration absorber shown in FIG. 5, in which the resonance frequencies of the MEMS mirrors and the movable absorbing portions 50 of the vibration absorber 6 are both 1.2 kHz. A dashed line depicts the vibration transmissibility of a known structure, which is the same as that shown in FIG. 1. The structure shown in FIG. 5 has a damper structure, in which the double-layered vibration-proof rubber members 5 and 5′ are used. Thus, the vibration attenuation capability is more than double that of the known structure. Vibration is sufficiently attenuated at a frequency region 60, which corresponds to the resonance frequency of the MEMS mirrors 45.

### Structure of Vibration Absorber for Casing

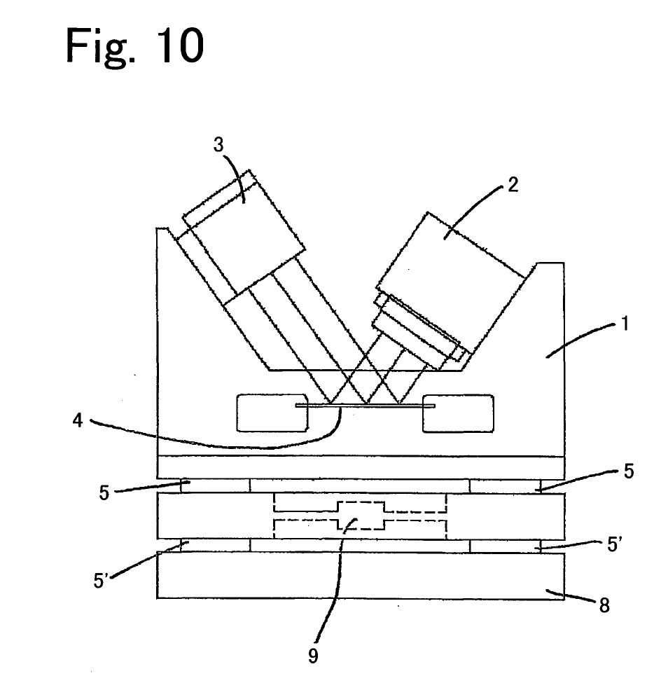

FIG. 10 shows a structure of a vibration absorber for the casing. In FIG. 10, components the same as those shown in FIG. 2 are denoted by the same reference numerals so as to make explanation thereof unnecessary. The structure shown in FIG. 10 differs from that shown in FIG. 2 in terms of the function of the vibration absorber 6. The vibration absorber 6 has a vibration absorbing portion 9 for the casing. The casing 1, when it receives a vibration having a frequency equal to the resonance frequency of the substantially V-shaped inclined surface structure from the outside, resonates and vibrates. The vibration of the casing I disturbs the optical path. To prevent this, the vibration absorber 6 in FIG. 10 has the vibration absorbing portion 9 for the casing therein, which absorbs a vibration having a frequency the same as the resonance frequency of the casing 1. The structure of the vibration absorbing portion 9 for the casing may be the same as those of the movable absorbing portions 50, 50′, and 50″ shown in FIGS. 5, 6, and 7, respectively, for example, as long as their resonance frequencies are the same as the resonance frequency of the casing 10. Further, the vibration absorber 6 of FIG. 10 may have the movable absorbing portions 50, 50′, and 50″ having the same resonance frequency as the MEMS mirrors 45.

### Structure of Second MEMS Device

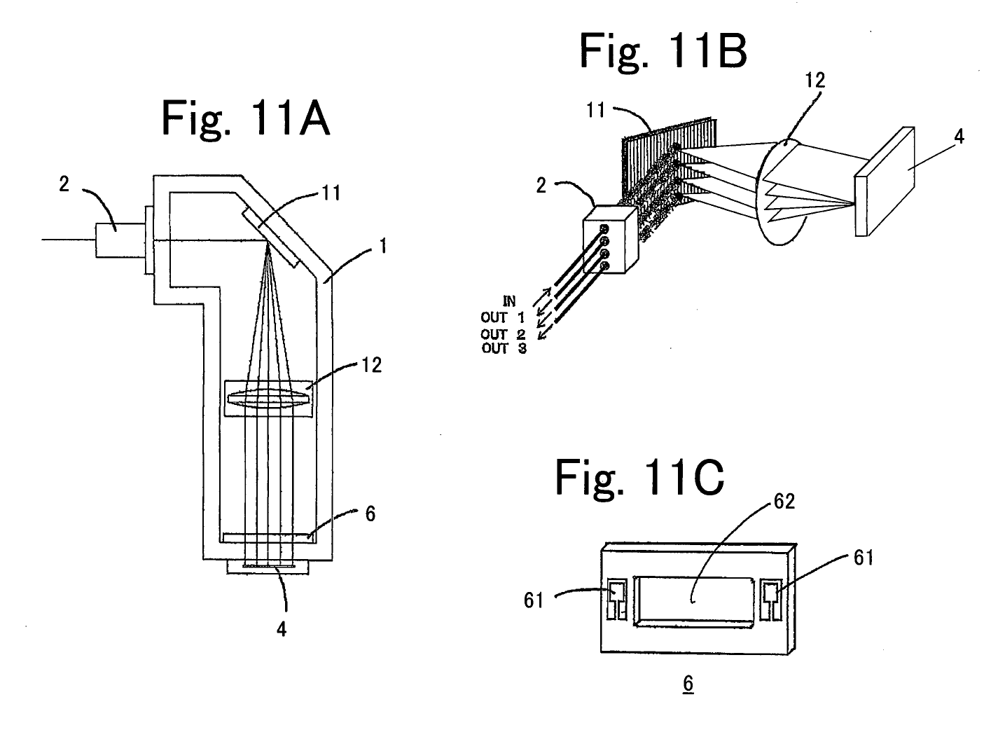

FIGS. 11A to 11C show a structure of a second MEMS device, which is a wavelength selective switch using MEMS elements. FIGS. 11A and 11B are a top view and a perspective view of the wavelength selective switch, respectively, and FIG. 11C shows the structure of the vibration absorber 6. The second MEMS device includes MEMS elements each having a movable part having a single axis structure. Light entering from the optical input/output portion 2 is split by a spectroscopic device 11. The light split by the spectroscopic device 11 enters the MEMS mirror array 4 through a lens 12. The MEMS mirrors of the MEMS mirror array 4 reflect the light back onto the lens 12. The light reflected at the MEMS mirror array 4 returns to the optical input/output portion 2 via the spectroscopic device 11. The MEMS mirror array 4 includes a plurality of MEMS mirrors arranged in directions in which the spectroscopic device 11 splits the light. By moving the MEMS mirrors in the direction perpendicular to the direction in which the light is split, the position in the spectroscopic device 11 at which the light beam is reflected back can be changed. By adjusting the control angles of the MEMS mirrors, light beams can be reflected back to different output ports of the optical input/output portion 2, in accordance with their wavelengths. The vibration absorber 6 is disposed between the lens 12 and the MEMS mirror array 4. In FIG. 11A, the vibration absorber 6 is provided near the MEMS mirror array 4.

FIG. 11C is a front view of the vibration absorber 6. The vibration absorber 6 includes an aperture 62 at the center thereof for allowing the optical path to extend to the MEMS mirror array 4. The vibration absorber 6 further includes movable absorbing portions 61 arranged on both sides of the aperture 62. The structure of the movable absorbing portion 61 of the vibration absorber 6 is the same as that of the movable absorbing portions 50, 50′, and 50″ shown in FIGS. 5 to 7, respectively. When these pseudo-MEMS elements of the vibration absorbing structure are subject to an externally applied vibration or impact, they oscillate and absorb the vibration energy. This reduces the resonance amplitude of the MEMS mirrors, and reduces influence of the vibration or impact on optical paths.

The above-described embodiments can be combined, if necessary.

What is claimed is:

1. A micro-electro-mechanical systems (MEMS) device, comprising:
a substrate;
a MEMS having a movable part having a resonance frequency on the substrate;
a movable absorber for absorbing a vibration in accordance with the resonance frequency so as to vibrate itself.

2. The MEMS device of the claim 1, wherein the MEMS and the movable absorber are a similarly shape.

3. The MEMS device of the claim 1, wherein the MEMS is capable of moving a plurality of pivot axes; and the movable absorber is capable of moving a plurality of pivot axes in accordance with the MEMS.

4. The MEMS device of the claim 1, further comprising an attenuator for attenuating a magnitude of the vibration of the movable absorber, and arranged on the movable absorber.

5. The MEMS device of the claim 1, further comprising a for accommodating the substrate and the movable absorber; and a casing vibration absorber for absorbing a vibration in accordance with the resonance frequency of the casing so as to vibrate itself.

6. The MEMS device of the claim 1, further comprising a for accommodating the substrate and the movable absorber; and
a vibration-proof members for absorbing a vibration and arranged between the casing and the movable absorber.

7. A micro-electro-mechanical systems (MEMS) device, comprising:
a substrate;
a plurality of MEMSs having a movable part, respectively, on the substrate, the movable part having a resonance frequency;
a plurality of movable absorbers for absorbing a vibration in accordance with the resonance frequency of the MEMSs so as to vibrate itself.

8. The MEMS device of the claim 7, wherein the movable absorbers have deferent moments of inertia.

9. The MEMS device of the claim 7, wherein the movable absorbers have deferent resonance frequencies.

10. The MEMS device of the claim 7, further comprising an attenuator for attenuating a magnitude of the vibration of the movable absorber, and arranged on the movable absorbers.
